(19) United States
(12) Patent Application Publication
(10) Pub. No.: US 2013/0160852 A1
(43) Pub. Date: Jun. 27, 2013

(54) SOLAR CONCENTRATOR AND PRODUCTION METHOD

(71) Applicants: Wolfram Wintzer, Jena (DE); Peter Mühle, Jena (DE); Lars Arnold, Neustadt (DE); Alois Wilke, Buseck (DE); Hagen Goldammer, Jena (DE); Andreas Baatzsch, Jena (DE)

(72) Inventors: Wolfram Wintzer, Jena (DE); Peter Mühle, Jena (DE); Lars Arnold, Neustadt (DE); Alois Wilke, Buseck (DE); Hagen Goldammer, Jena (DE); Andreas Baatzsch, Jena (DE)

(73) Assignee: DOCTER OPTICS GMBH, Neustadt an der Orla (DE)

(21) Appl. No.: 13/819,429

(22) PCT Filed: Apr. 13, 2011
(86) PCT No.: PCT/EP11/01847

§ 371 Date: Feb. 27, 2013

(30) Foreign Application Priority Data
Aug. 30, 2010 (DE) 102010035865.7

(51) Int. Cl. G02B 19/00; H01L 31/0232

(52) U.S. Cl. CPC G02B 19/0042; H01L 31/0232
USPC 136/259; 359/642; 264/1.24

(57) ABSTRACT

The invention relates to a solar concentrator, comprising a solid body made of a transparent material, which has a light coupling surface and a convex light decoupling surface, wherein the solid body has a light guide part between the light coupling surface and the convex light decoupling surface, wherein said light guide part is tapered in the direction of the convex light decoupling surface. The invention further relates to a production method, wherein the material is precision-molded between two molds.

### CROSS REFERENCE TO RELATED APPLICATIONS

This application is the U.S. national phase of PCT/EP2011/001847 filed Apr. 13, 2011. PCT/EP2011/001847 claims the benefit under the Convention of German Patent Application No. 10 2010 035 865.7 filed Aug. 30, 2010.

### FIELD OF THE INVENTION

The invention concerns a solar concentrator made from transparent material, wherein the solar concentrator comprises a light entry (sur)face (also referred to as light coupling face e.g. in patent literature), a light exit (sur)face (also referred to as light decoupling face e.g. in patent literature), and a light guide portion between the light entry surface and the light exit is surface (it should be noted that in context with the light entry [coupling] and light exit [decoupling] areas described and outlined in the following specification and claims the term “face”, only, is used for the sake of simplicity and is to include the term and meaning of “surface” as well), the light guide portion tapering in the direction of the light exit face. The invention, moreover, concerns a method for manufacturing such a solar concentrator.

### BACKGROUND INFORMATION

FIG. 1 shows a known solar concentrator 101 which is depicted in FIG. 2 by way of a cross-sectional representation. The solar concentrator 101 comprises a light entry face 102 and a ground light exit face 103 as well as a light guide portion 104 located between the light entry face 102 and the light exit face 103 and tapering in the direction of the light exit face 103. Reference numeral 105 denotes a light guide portion surface which restricts the light guide portion 104 between the light entry face 102 and the light exit face 103.

Document EP 1 396 035 B1 discloses a solar concentrator module comprising, on its frontal side, a front lens and, on its rear side, a receiver cell, and, between the front lens and the receiver cell, a reflector which has inclined side walls along at least two opposing sides of the receiver cell, and, in the center of the module, a flat vertical reflector, wherein the sidewall reflectors are shortened such that the ratio between the height H of the generator and the focal length F of the lens lies between 0.6 and 0.9. US 2006/0016448 A1 discloses an apparatus for the focusing of light.

It is an object of the invention to reduce the costs for the production of solar concentrators. It is a further object of the invention to manufacture solar concentrators of a particularly high quality within restricted budget conditions.

### SUMMARY

The aforementioned object is achieved by a method for producing a solar concentrator from transparent material, wherein the solar concentrator comprises a light entry face, a convex light exit face and a light guide portion located between the light entry face and the convex light exit face and tapering (linearly or non-linearly) in the direction of the light exit face, which light guide portion is advantageously restricted by a light guide portion surface between the light entry face and the convex light exit face, and wherein, between a first mold, adapted for molding the light entry face, and at least one second mold having a concave portion adapted for molding the light exit face, the transparent material is blank molded, in particular two-sidedly, for creating the solar concentrator, wherein the transparent material, particularly at the beginning of exerting the molding pressure onto the transparent material, is drawn into the second mold by means of a depression, i.e. pressure below atmosphere.

In the sense of the invention, a solar concentrator is, in particular, a secondary concentrator. In the sense of the invention, transparent material is particularly glass. In the sense of the invention, the term blank molding is, in particular, to be understood in a manner that an optically operative and efficient surface is to be molded under pressure such that any subsequent finishing or further treatment may be dispensed with or does not apply or will not have to be provided for. Consequently, it is particularly provided that, after blank molding, the light exit face is not ground, i.e. it will not be treated by grinding.

A light guide portion surface, when taken in the sense of the invention, is, in particular, inclined by at least 0.1° with respect to the optical axis of the solar concentrator. A light guide portion surface, in the sense of the invention, is, in particular, inclined by no more than 3° with respect to the optical axis of the solar concentrator. An optical axis of the solar concentrator is, in particular, an orthogonal or the orthogonal of the light exit face. The light guide portion surface may be coated.

In the sense of the invention, a light exit or light decoupling face is, in particular, convex if it is convex over its total area. In the sense of the invention, a light exit or decoupling face is, in particular, convex if it is convex over essentially its total area. A light exit or decoupling face, in the sense of the invention, is, in particular, convex if it is convex at least in a partial area.

It is, in particular, provided that the transparent material be cut as liquid glass and thus be positioned within the second mold such that the cutting grain or seam lies outside the optical area. In squeeze or pressure molding it is, in particular, provided that the first mold and the second mold are positioned in relation to each other and moved to approach each other. After pressure molding it is, in particular, provided that the solar concentrator is cooled on an appropriate support means on a cooling conveyor. According to an expedient embodiment the solar concentrator is provided with a supporting frame. Herein, it is, in particular, provided that fluctuations in weight of the supplied liquid glass are adjusted by varying the support flange. It may also be provided that a heat treatment cycle be applied in which a portion of excessive glass will be collected and thereafter (following the removal from the mold) heating will be performed on the flange with an extremely hot flame until this portion drops off.

In an embodiment of the invention, the transparent material, in particular in the outer region thereof, is drawn into the second mold by means of the depression at least partially during said blank molding. In an embodiment of the invention, the depression is at least 0.5 bar. In an embodiment of the invention, the depression corresponds, in particular, to vacuum. In an embodiment of the invention, the transparent material has a viscosity of no more than 10^{4,5} dPas immediately before molding.

In an embodiment of the invention, the concave portion for molding the convex light exit (light decoupling) face is curved with a radius of curvature of less than 30 mm. In a furthermore advantageous embodiment of the invention, the concave portion for molding the convex light exit face is curved such that the (maximum) deviation of contour from the ideal plane of the mold is less than 100 μm. In the sense of the invention, an ideal plane of the mold is, in particular, a plane through the transition of the component (in particular of the second mold) provided for molding the light guide portion surface, to the component for molding the convex light exit face. In a furthermore advantageous embodiment of the invention, the concave portion for molding the convex light exit face is curved such that the (maximum) deviation of contour from the ideal plane of the mold is more than 1 μm.

In a furthermore advantageous embodiment of the invention, the first mold is heated and/or cooled. In an embodiment of the invention, the second mold is heated and/or cooled.

In a further favorable embodiment of the invention, the second mold is at least two-part. In an embodiment of the invention, the second mold has a gap, particularly a circumferential gap, specifically an annular gap, in the region forming the transition between the light exit face and the light guide portion surface. Herein, it is, in particular, provided that the gap is or will be formed between a first component of the second mold and a second component of the second mold. In an embodiment of the invention the gap has a width of between 10 μm and 40 μm. In a further expedient embodiment of the invention, the depression is generated in said gap.

The aforementioned object is, moreover, achieved by a method for producing a solar module, wherein a solar concentrator produced by a method according to any one of the preceding features is, with its light exit face, connected to, in particular cemented to a photovoltaic element (for generating electric energy from sunlight) and/or is fixedly aligned with respect to a photovoltaic element (for generating electric energy from sunlight).

The aforementioned object is, furthermore, achieved by a solar concentrator in particular produced in accordance with a method according to any one of the preceding features and having a solid body from transparent material, which solid body comprises a light entry face and a convex light exit face, wherein the solid body comprises a light guide portion (located) between the light entry face and the convex light exit face tapering (linearly or non-linearly) in the direction of the convex light exit face, which light guide portion is advantageously restricted by a light guide portion surface and/or located between the light entry face and the convex light exit face, and wherein the convex light exit face is curved
with a radius of curvature of more than 30 mm and/or
such that the maximum of its contour deviation or its (maximum) deviation of contour from the ideal plane of the mold is less than 100 μm.

The aforementioned object is, furthermore, achieved by a solar concentrator in particular produced in accordance with a method according to any one of the preceding features from transparent material, which solar concentrator comprises a light entry face, a convex light exit face, and a light guide portion located between the light entry face and the convex light exit face and tapering (linearly or non-linearly) in the direction of the convex light exit face, which light guide portion is advantageously restricted by a light guide portion surface and/or located between the light entry face and the convex light exit face, and wherein the convex light exit face is curved
with a radius of curvature of more than 30 mm and/or
such that the maximum of its contour deviation or its (maximum) deviation of contour from the ideal plane of the mold is less than 100 μm.

In the sense of the invention, an ideal plane is, in particular, a plane through the transition of the light guide portion surface to the light exit (light decoupling) face. In the sense of the invention, a light exit (light decoupling) plane is, in particular, a plane through the transition of the light guide portion surface to the light exit face. In the sense of the invention, a light exit (light decoupling) plane is, in particular, a plane parallel to the plane through the transition of the light guide portion surface to the light exit face, through the transition of the light guide portion surface to the light exit face, when said plane is placed through the apex (of the curvature) of the light exit face. In the sense of the invention, a light exit plane is, in particular, a plane orthogonal to the tapering light guide portion when said plane is placed through the apex (of the curvature) of the light exit face. In the sense of the invention, a light exit plane is, in particular, a plane orthogonal to the optical axis of the solar concentrator when said plane is placed through the apex (of the curvature) of the light exit face. In an advantageous embodiment of the invention, the convex light exit face is curved such that its (maximum) deviation of contour from the ideal plane or the light exit face, respectively, is more than 1 μm.

In an embodiment of the invention the light guide portion surface merges into the light exit face with a continuous first derivative. In yet an embodiment of the invention the light guide portion surface merges into the light exit face with a curvature the radius of which (curvature) amounts to no more than 0.25 mm, in particular to no more than 0.15 mm, preferably to no more than 0.1 mm. According to a yet further expedient embodiment of the invention the radius of curvature is more than 0.04 mm.

In an embodiment of the invention the convex light exit face is blank molded. In a still further advantageous embodiment of the invention the particularly curved transition from the light guide portion surface to the light exit face is blank molded. In an embodiment of the invention, the light entry face is blank molded. In an embodiment of the invention, the light entry face is convex or planar. The light entry face may be shaped non-spherical or spherical. It may also be provided for that the light entry face is designed as a free form or shape. The light exit face may be designed to be spherical or non-spherical. It may also be provided for that the light exit face is designed as a free form or shape.

The aforementioned object is, furthermore, achieved by a solar module comprising an aforementioned solar concentrator or a solar concentrator from transparent material and produced in accordance with any of the aforementioned methods, respectively, wherein the solar concentrator, by means of its convex light exit face is connected to a photovoltaic element.

In an embodiment of the invention, the solar module comprises a heat sink or cooling body on which the photovoltaic element is mounted. In a furthermore advantageous embodiment of the invention, a retaining bracket for the solar concentrator is arranged on the heat sink body. In a furthermore advantageous embodiment of the invention, the solar module comprises a retaining bracket for the solar concentrator. In an embodiment of the invention, the retaining bracket fixedly attaches the solar concentrator to a support frame of the solar concentrator. In a still further advantageous embodiment of the invention, the solar module has a lens for aligning and directing sunlight onto the light entry face of the solar concentrator.

The aforementioned object is, furthermore, achieved by a solar module comprising a solar concentrator in particular produced in accordance with a method according to any one of the preceding features and having a solid body from transparent material, which solid body comprises a light entry face and a convex light exit face, wherein the solid body comprises a light guide portion located between the light entry face and the convex light exit face and tapering (linearly or non-linearly) in the direction of the convex light exit face, which light guide portion is restricted by a light guide portion surface and/or located, respectively, between the light entry face and the convex light exit face, wherein the solar concentrator is connected to a photovoltaic element with its convex light exit face.

The aforementioned object is, furthermore, achieved by a solar module comprising a solar concentrator in particular produced in accordance with a method according to any one of the preceding features and made from transparent material, which solar concentrator comprises a light entry face, a convex light exit face, and a light guide portion arranged between the light entry face and the convex light exit face and tapering (linearly or non-linearly) in the direction of the convex light exit face, which light guide portion, advantageously, is restricted by a light guide portion surface and/or arranged, respectively, between the light entry face and the convex light exit face, wherein the solar concentrator is connected to a photovoltaic element with its convex light exit face.

In an advantageous embodiment of the invention, the light guide portion surface merges into the convex light exit face with a continuous first derivative. In a furthermore advantageous embodiment of the invention, the light guide portion surface merges into the convex light exit face with a curvature, the radius of which curvature is no more than 0.25 mm, in particular no more than 0.15 mm, advantageously no more than 0.1 mm. According to a furthermore advantageous embodiment of the invention, the radius of curvature is more than 0.04 mm.

In an embodiment of the invention, the solar module comprises a heat sink body (cooling body) on which the photovoltaic element is mounted. In a furthermore advantageous embodiment of the invention, a retaining bracket for the solar concentrator is arranged on the heat sink body. In a furthermore advantageous embodiment of the invention, the solar module comprises a retaining bracket for the solar concentrator. In an embodiment of the invention, the retaining bracket fixedly attaches the solar concentrator to a support frame of the solar concentrator. In a still further advantageous embodiment of the invention, the solar module has a lens for aligning and directing sunlight onto the light entry face of the solar concentrator.

In an embodiment of the invention, the convex light exit face is curved with a curvature of more than 30 mm. In an advantageous embodiment of the invention, the convex light exit face is curved such that its (maximum) deviation of contour from the ideal plane or the light exit plane, respectively, is less than 100 μm. In the sense of the invention, an ideal plane is, in particular, a plane through the transition of the light guide portion surface to the light exit face. In the sense of the invention, a light exit plane is, in particular, a plane through the transition of the light guide portion surface to the light exit face. In the sense of the invention, a light exit plane is, in particular, a plane parallel to the plane through the transition of the light guide portion surface into the light exit face, when said plane is located through the apex (of the curvature) of the light exit face. In the sense of the invention, a light exit plane is, in particular, a plane orthogonal to the tapering light guide portion when said plane is located through the apex (of the curvature) of the light exit face. In the sense of the invention, a light exit plane is, in particular, a plane orthogonal to the tapering light guide portion, when said plane is located through the apex (of the curvature) of the light exit face. In the sense of the invention, a light exit plane is, in particular, a plane orthogonal to the optical axis of the solar concentrator when said plane is located through the apex (of the curvature) of the light exit face. In an advantageous embodiment of the invention, the convex light exit face is curved such that its (maximum) deviation of contour from the ideal plane or the light exit face, respectively, is more than 1 μm.

In a furthermore advantageous embodiment of the invention, the convex light exit face is blank molded. In a furthermore advantageous embodiment of the invention, the particularly curved transition from the light guide portion surface to the light exit face is blank molded. In a furthermore advantageous embodiment of the invention, the light entry face is blank molded. In a furthermore advantageous embodiment of the invention, the light entry face is convex or planar. The light entry face may be shaped non-spherical or spherical. It may also be provided that the light entry face be designed as a free form or shape. The light exit face may be shaped non-spherical or spherical. It may also be provided that the light exit face be designed as a free form or shape.

The aforementioned object is, furthermore, achieved by a solar module comprising an aforementioned solar concentrator or a solar concentrator from transparent material and produced in accordance with any of the aforementioned methods, respectively, wherein the solar concentrator is connected to a photovoltaic element by means of its convex light exit face.

The invention furthermore concerns method for generating electric energy, wherein sunlight is made to enter into the light entry face of a solar concentrator of an aforementioned solar module, in particular by means of a primary solar concentrator.

Further advantages and details of the present invention will become apparent from the following description of preferred examples of embodiment.

### BRIEF DESCRIPTION OF THE DRAWINGS

FIG. 1 shows a perspective representation of a known solar concentrator;

FIG. 2 shows a cross-sectional representation of the solar concentrator as shown in FIG. 1;

FIG. 3 shows an example of embodiment of a solar concentrator in accordance with the present invention;

FIG. 4 shows a method for manufacturing a solar concentrator in accordance with FIG. 3;

FIG. 5 shows an enlarged cut-out of a solar concentrator in accordance with FIG. 3;

FIG. 6 shows an alternative method for manufacturing a solar concentrator in accordance with FIG. 3; and

FIG. 7 shows an example of an embodiment of a solar module including a solar concentrator in accordance with the present invention.

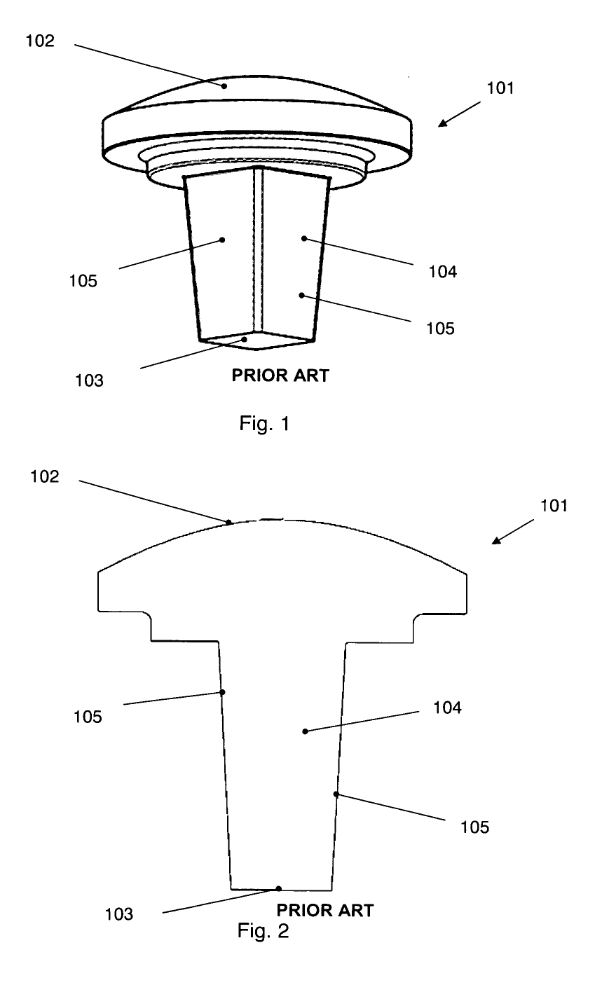

### DETAILED DESCRIPTION

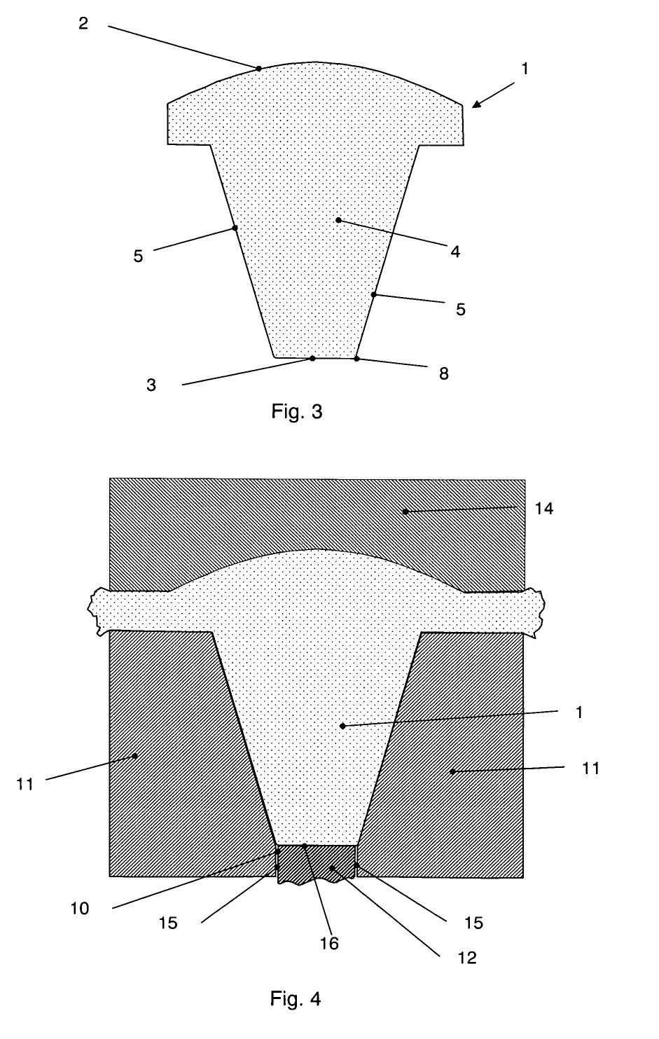

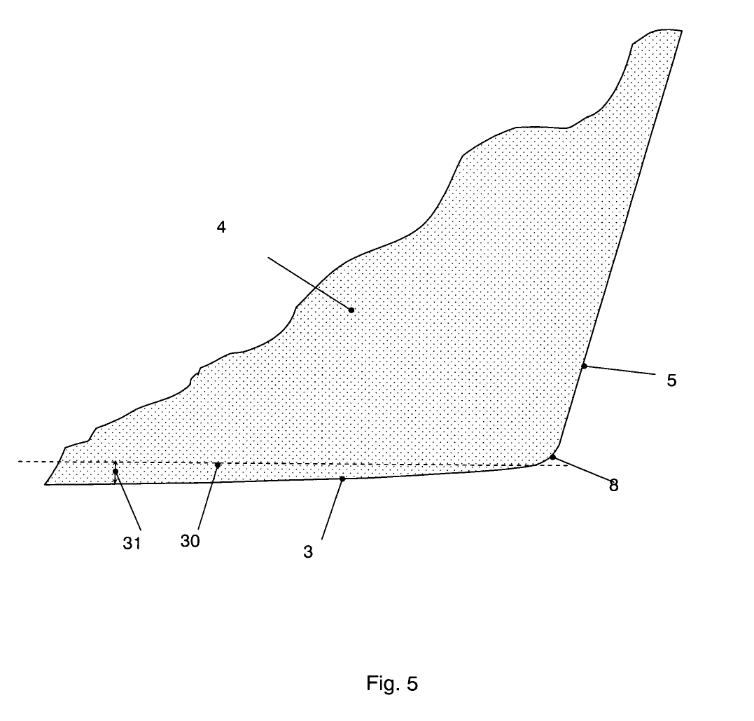

FIG. 3 shows, by way of a cross-sectional representation, an example of embodiment of a solar concentrator 1 according to the present invention. The solar concentrator comprises a light entry (sur)face 2 and a blank-molded light exit (sur)face 3 as well as a light guide portion 4 located between the light entry face 2 and the light exit face 3 and tapering in the direction of the light exit face 3. Reference numeral 5 designates a light guide portion surface which restricts the light guide portion 4 between the light entry face 2 and the light exit face 3. Herein, the light guide portion surface 5 merges—as has been represented in greater detail in FIG. 5—into the light exit face with a curvature 8 whose radius of curvature is approximately 0.1 mm. The protruding press flange or excess-press material, respectively, is removed (mechanically and/or thermally) after molding under pressure.

FIG. 4 shows a method for manufacturing a solar concentrator 1 according to FIG. 3. Herein, liquid glass having a viscosity of no more than 10^{4,5} dPas is fed into a mold 10 and, by means of a mold 14, pressed resp. molded under pressure into the shape of the solar concentrator 1. The mold 10 comprises a partial mold 11 and a partial mold 12 which, in a centered manner, is arranged within the partial mold 11. A circumferential gap 15 is provided between the partial mold 11 and the partial mold 12, which gap has a width of between 10 μm and 40 μm. In the circumferential gap 15 a depression in the order of a vacuum is generated when pressing together the molds 10 and 14. The partial mold 12 comprises a concave portion 16 for forming the convex light exit face 3.

In an advantageous embodiment the convex light exit face 3 is curved, respectively, with a radius of curvature of more than 30 mm or such that the maximum of its deviation of contour 31 from the ideal plane or the light exit face 30 is less than 100 μm. In the present example of embodiment the convex light exit face 3 is curved such that the maximum of its contour deviation 31 from the ideal plane or the light exit face 30, respectively, is less than 100 μm.

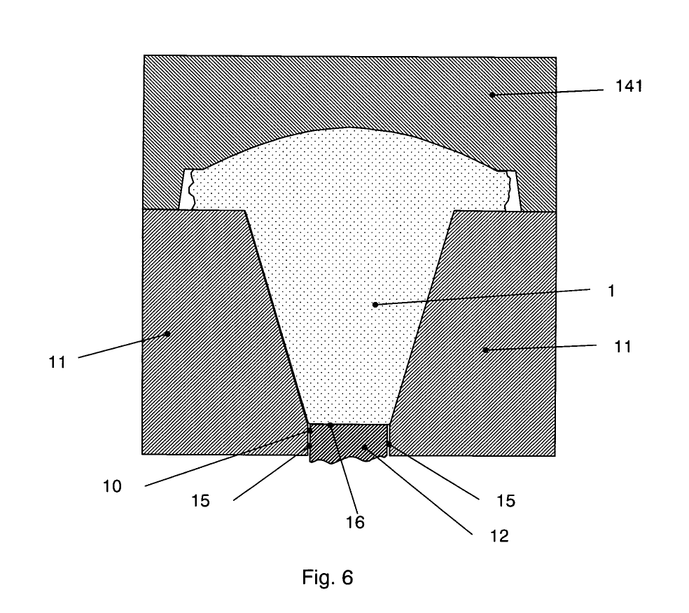

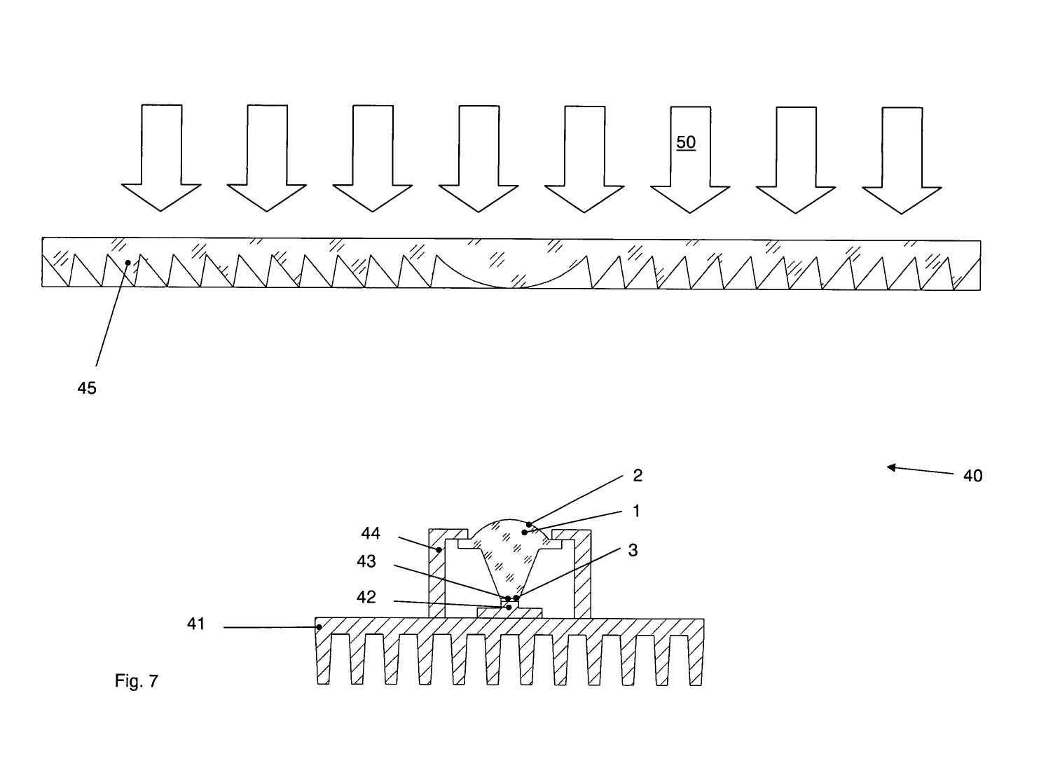

FIG. 6 shows an optional method for manufacturing a solar concentrator 1. Herein, the mold 14 is substituted by a mold 141 which firmly bears on the partial mold 11.

FIG. 7 shows an example of embodiment of a solar module 40 including a solar concentrator 1 in accordance with the present invention. The solar module 40 comprises a heat sink or cooling body 41 on which a photovoltaic element 42 and retention means 44 for the solar concentrator 1 are arranged. The light exit face 3 is connected to the photovoltaic element 42 by means of a layer 43 of adhesive material. The solar module 40 furthermore comprises a primary solar concentrator 45 designed as a Fresnel lens or drum lens for aligning sunlight 50 with respect to the light entry face 2 of the solar concentrator 1 arranged or designed or provided, respectively, as a secondary solar concentrator. Sunlight fed into the solar concentrator 1 via the light entry face 2 exits via the light exit face 3 of the solar concentrator 1 and encounters the photovoltaic element 42.

Elements, dimensions and angles as used in FIGS. 3 to 6, respectively, have been drafted in consideration of simplicity and clarity and not o necessarily to scale. For example, the orders of magnitude of some of the elements, dimensions and angles, respectively, have been exaggerated with regard to other elements, dimensions and angles, respectively, in order to enhance comprehension of the examples of embodiment of the present invention.

1.-36. (canceled)

37. A solar concentrator having a solid body of transparent material, which solid body comprising:
a light entry face;
a convex light exit face curved with a radius of curvature of more than 30 mm; and
a light guide portion between the light entry face and the convex light exit face tapering in the direction of the convex light exit face, which light guide portion is restricted by a light guide portion surface between the light entry face and the convex light exit face.

38. The solar concentrator as claimed in claim 37, wherein the light guide portion surface merges into the light exit face with a continuous first derivative.

39. The solar concentrator as claimed in claim 37, wherein the light guide portion surface merges into the light exit face with a curvature whose radius is no more than 0.25 mm

40. The solar concentrator as claimed in claim 37, wherein the convex light exit face is curved such that the maximum of its deviation of contour from a light exit plane is more than 1 μm.

41. The solar concentrator as claimed in claim 37, wherein the transition from the light guide portion surface to the light exit face is blank molded.

42. The solar concentrator as claimed in claim 37, wherein the convex light exit face is blank molded.

43. A solar concentrator made from transparent material, which solar concentrator comprising:
a light entry face;
a convex light exit face curved such that the maximum of its deviation of contour from a light exit plane is less than 100 μm; and
a light guide portion between the light entry face and the convex light exit face tapering in the direction of the convex light exit face.

44. The solar concentrator as claimed in claim 43, wherein the convex light exit face is curved such that the maximum of its deviation of contour from the light exit plane is more than 1 μm.

45. The solar concentrator as claimed in claim 43, wherein the convex light exit face is blank molded.

46. A solar module comprising:
a photovoltaic element; and
a solar concentrator made from transparent material, the solar concentrator comprising:
a light entry face;
a convex light exit face connected to the photovoltaic element; and
a light guide portion between the light entry face and the convex light exit face tapering in the direction of the convex light exit face.

47. The solar module as claimed in claim 46, wherein the convex light exit face is curved with a radius of curvature of more than 30 mm.

48. The solar module as claimed in claim 46, wherein the convex light exit face is curved such that the maximum of its deviation of contour from a light exit plane is more than 1 μm.

49. The solar module as claimed in claim 48, wherein the convex light exit face is curved such that the maximum of its deviation of contour from the light exit plane is not more than 100 μm.

50. The solar module as claimed in claim 48, wherein the convex light exit face is curved with a radius of curvature of more than 30 mm.

51. The solar module as claimed in claim 46, wherein the convex light exit face is blank molded.

52. A method for generating electric energy, the method comprising:
providing a photovoltaic element;
providing a solar concentrator made from transparent material, the solar concentrator comprising:
a light entry face;
a convex light exit face; and
a light guide portion between the light entry face and the convex light exit face tapering in the direction of the convex light exit face;
cementing/gluing the convex light exit face to the photovoltaic element; and
making sunlight to enter into the light entry face.

53. A method for producing a solar concentrator from transparent material, wherein the solar concentrator comprises a light entry face, a convex light exit face and a light guide portion located between the light entry face and the convex light exit face and tapering in the direction of the light exit face, which light guide portion is restricted by a light guide portion surface between the light entry face and the convex light exit face; the method comprising:
providing a first mold, adapted for molding the light entry face;
providing at least one second mold having a concave portion adapted for molding the convex light exit face;
drawing transparent material into the second mold by means of a depression; and
blank molding the transparent material between said first mold and said second mold for creating the solar concentrator.

54. The method as claimed in claim 53, wherein immediately before molding, the transparent material has a viscosity of no more than 10^{4,5} dPas.

55. The method as claimed in claim 53, wherein the second mold is at least two-part.

56. The method as claimed in claim 53, wherein the second mold has a gap in the region forming the transition between the light exit face and the light guide portion surface.

57. The method as claimed in claim 56, the depression is generated in said gap.

58. The method as claimed in claim 56, wherein the gap has a width of between 10 μm and 40 μm.

59. The method as claimed in claim 58, the depression is generated in said gap.
